(19) United States
(12) Patent Application Publication
(10) Pub. No.: US 2011/0017703 A1
(43) Pub. Date: Jan. 27, 2011

(54) SELECTIVE PLANARIZATION METHOD AND DEVICES FABRICATED ON PLANARIZED STRUCTURES

(75) Inventors: Dorota Temple, Cary, NC (US); Dean Michael Malta, Cary, NC (US); Christopher A. Bower, Raleigh, NC (US)

Correspondence Address: OBLON, SPIVAK, MCCLELLAND MAIER & NEUSTADT, L.L.P., 1940 DUKE STREET, ALEXANDRIA, VA, 22314, US

(73) Assignee: Research Triangle Institute, Research Triangel Park, NC (US)

(21) Appl. No.: 12/921,482

(22) PCT Filed: Feb. 13, 2009
(86) PCT No.: PCT/US09/33984

§ 371 Date: Sep. 8, 2010

Related U.S. Application Data
(60) Provisional application No. 61/036,814, filed on Mar. 14, 2008.

(51) Int. Cl. H05K 3/00; C23F 1/04

(52) U.S. Cl. 216/17; 216/83; 216/95; 156/345.11

(57) ABSTRACT

A method and system for treating a surface structure of a workpiece. The method provides a carrier-gel to the surface structure of the workpiece. The carrier-gel includes an etchant for selectively etching a first material of the surface structure and has a gel particle size larger than the surface structure. The method etches the first material from the surface structure by a reaction of the etchant included in the carrier-gel with the first material of the surface structure in order to remove a part of the first material from the surface structure for subsequent device fabrication. The system includes a chemical reactor supporting the workpiece. The chemical reactor is configured to flow the carrier-gel noted to the surface structure of the workpiece in order to remove the first material from the surface structure.

### BACKGROUND OF THE INVENTION

1. Field of the Invention

This application is directed to methods for selective planarization of advanced integrated circuit components and devices formed on the planarized structures.

2. Description of the Related Art

Three-dimensional (3D) integration of microelectronic circuits is an emerging market in which several approaches are currently under implementation. In one 3D approach, referred to as a “vias last” approach, a first device substrate is bonded to a second device substrate (both of which contain active device elements). Deep vias are bored through the second device substrate until metal pads on the first device substrate are reached. The exposed metal pads and the bored vias have a via-metal deposited thereon and therein, respectively, to form a conducting electrical interconnect between the first and second device substrates.

However, the process of depositing the via-metal causes a metal layer to form on a surface of the bonded substrates (i.e., an overburden). Chemical Mechanical Polishing (CMP) has traditionally been used for the removal of the metal layer (e.g., copper), from the surface of the substrates, such as integrated circuit wafers. Furthermore, CMP may also be applied for planarization. The removal and subsequent patterning of metal from stacked die-to-die and die-to-wafer, as required in the processing of 3D integrated circuits, for example, pose many challenges to CMP and other metal removal processes.

Currently, chemical mechanical polishing (CMP) is typically used to remove metallic overburden and dielectrics from the surfaces of IC wafers. Using CMP, metal is removed from the top surface of a substrate, as a polisher rubs off the overburden of the deposited metal layer. However, the CMP technique is not suited for circumstances where the substrate surface is irregular. Furthermore, CMP faces serious obstacles in handling stacked die parts (in either die or die-to-wafer configurations). The high topography and sharp edges of the die may damage the CMP pads, and the material removal rate will likely not be uniform across the surface of the die.

### SUMMARY OF THE INVENTION

In one embodiment of the invention, there is provided a method for treating a surface structure of a workpiece. The method provides a carrier-gel to the surface structure of the workpiece. The carrier-gel includes an etchant for selectively etching a first material of the surface structure and has a gel particle size larger than the surface structure. The method etches the first material from the surface structure by a reaction of the etchant included in the carrier-gel with the first material of the surface structure in order to remove a part of the first material from the surface structure for subsequent device fabrication.

In another embodiment of the invention, there is provided a method for substrate structure processing. The method includes opening at least one via in a workpiece, filling the at least one via with a via-fill material, flowing a carrier-gel across a surface of the workpiece having the via-fill material thereon, and etching an excess of the via-fill material by an etchant included in the carrier-gel flowing across the surface of the workpiece.

In another embodiment of the invention, there is provided a system for treating a surface structure of a workpiece. The system includes a chemical reactor supporting the workpiece. The chemical reactor is configured to flow a carrier-gel to the surface structure of the workpiece. The carrier-gel includes an etchant for selectively etching a first material of the surface structure and having a gel particle size larger than the surface structure. The chemical reactor etches the first material from the surface structure by a reaction of the etchant included in the carrier-gel with the first material of the surface structure in order to remove a part of the first material from the surface structure for subsequent device fabrication.

In another embodiment of the invention, there is provided a system for substrate structure processing. The system includes a via former configured to form at least one via hole in a workpiece, a depositor configured to fill the at least one via hole with a via-fill material, and a chemical reactor supporting the workpiece and configured to flow a carrier-gel across a surface of the workpiece having the via-fill material thereon to etch excess of the via-fill material by an etchant included in the carrier-gel.

It is to be understood that both the foregoing general description of the invention and the following detailed description are exemplary, but are not restrictive of the invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a schematic illustrating how a gel medium flows over a die-to-die sample according to an embodiment of the invention;

FIGS. 1B and 1C are magnified views of FIG. 1A that illustrate how the gel medium etches the surface material while not running into desired features according to an embodiment of the invention;

FIG. 2A is schematic of an exemplary die stacked and electrically integrated with another die to which an embodiment of the invention is applied;

FIG. 2B is a 3-D illustration of the exemplary die-to-die configuration of FIG. 2A;

FIG. 3A is a cross section of an exemplary die-to-wafer configuration to which an embodiment of the invention is applied;

FIG. 3B is a 3-D schematic of the exemplary die-to-wafer configuration of FIG. 3A;

FIG. 4 is a schematic illustration of an exemplary device package to which an embodiment of the invention is applied;

FIGS. 5A and 5B are schematic illustrations of an appearance of a stacked die with patterned features following the material removal process according to an embodiment of the invention;

FIG. 6A is a cross sectional scanning electron microscope (SEM) micrograph showing an overburden to be removed from the top of a stacked die;

FIG. 6B is a schematic representation of the cross sectional SEM of FIG. 6A;

FIGS. 7A and 7B are two SEM micrographs of the surface of the stacked die following removal of the top copper using a loaded gel medium according to an embodiment of the invention;

FIG. 8A is a schematic representation of a SEM cross section micrograph showing the structure at the top of the copper interconnect following a surface copper removal process, according to an embodiment of the invention;

FIGS. 8B and 8C are schematic representations of the SEM micrographs of the surface of the stacked die following removal of the top copper using a loaded gel medium, according to an embodiment of the invention;

FIG. 9 is a flowchart illustrating a process of the invention for removing overburden and facilitating substrate stack integration;

FIG. 10 is a flowchart illustrating another process of the invention for removing overburden and facilitating substrate stack integration;

FIG. 11 is a schematic depicting the elements of a system for processing overburden layers and facilitation die or wafer integration; and

FIG. 12 is a schematic depicting a dual; damascene process using the carrier gel techniques of the invention for overburden removal.

### DETAILED DESCRIPTION OF THE INVENTION

This invention is directed to a system and method for removal and/or patterning of a material layer that exists on the surface of a structure on a workpiece. A material layer is removed, or patterned, by a gel medium carrying an etchant. The etchant is confined within the gel medium whose critical dimension can be on the order of 10-1000 microns. The method can be used to remove overburden layers such as for example copper overburdens without damaging structures, such as electrical interconnects or trenches containing the material to be removed. The invention is suited for treating these and other irregular surfaces. The invention provides advantages in that it is a relatively simple process, which requires relatively inexpensive equipment to be used.

According to one embodiment of the invention, there is provided a method for removing and/or patterning a material layer that exists on the surface of a stacked die or a stacked die on wafer. Conventionally, removal of over-deposited surface materials (e.g., the overburden) is performed by chemical mechanical planarization (CMP). However, this process (often used in dual damascene processing and performed on integrated circuit wafers) is not well suited for removal of material layers on a stacked die, or on wafers that are populated with stacked die. The raised topography of the die (or wafers populated with stacked die) tears and damages the CMP polishing pad being used, and results in a poor uniformity pattern due to increased pressure near the edge and corners of the stacked die. The invention, however, provides an efficient way to remove surface materials (e.g., copper overburden layers), that exist on the surfaces of stacked die, and to remove surface materials on a base wafer populated with stacked die (also referred to as die-to-wafer).

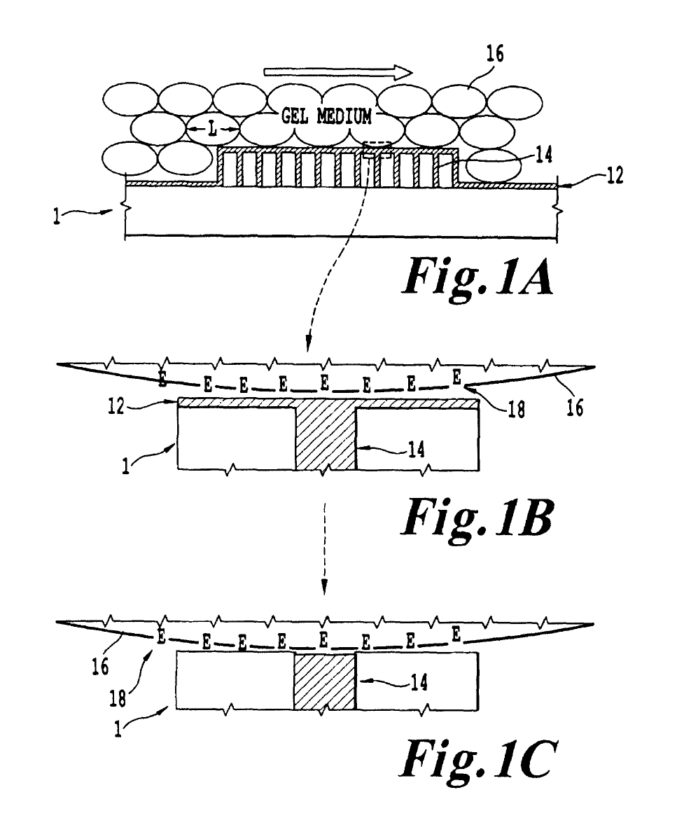

Referring now to the drawings, wherein like reference numerals designate identical or corresponding parts throughout the several views, FIG. 1A is a schematic illustrating how a gel medium flows over a die-to-die sample. In one embodiment, a stacked die or a stacked wafer 1 is submerged in a chamber (not shown) where a gel medium 16 is pumped to create a flow (e.g., a laminar flow) of the gel medium 16 across the workpiece (e.g., wafer 1). The gel medium 16 including an appropriate etchant E is transposed across the surface of a stacked die (or multiple die on wafer). Overburden material 12 is removed from the top surface of the stacked die and from the edges of the stacked die. However, the etchant E does not penetrate into small vertical interconnect structures, in the stacked die, due to the size (denoted as L) and etchant-trapping (ore retaining) nature of the gel medium. This embodiment allows for efficient and controlled removal of the material, such as for example excess metal overburden, from the tops of stacked die in die-to-die or die-to-wafer configurations.

Although the disclosure describes in various embodiments for the removal of an overburden layer the removal of copper, the invention is not so limited. It should be understood that the invention may be applied to the removal and/or patterning of other conductive and non-conductive material layers including dielectric layers in surface structures where it is desired to leave a material inside a via or a trench while removing the same material on the top of the structure. For example, materials which can be removed by the invention include materials such as aluminum, silicon oxide, silicon nitride, silicides, and other semiconductor device materials. For removal of surface materials, the gel medium includes a known etchant E for the particular material to be removed, and the gel medium (with the etchant) is applied for a sufficient amount of time to remove the overburden. Since the process with the oversized gel medium (i.e., a gel medium larger in size than the sized of the via structure or other surface feature containing the overburden) is self-limiting, the duration of time for application of the gel medium with the etchant is less constrained than it would be if the process were not self-limiting. Furthermore, in one embodiment of the invention, since the gel medium is circulated across the sample, the gel medium carries a first etchant for a first prescribed amount of time, and later can carry a second etchant in the gel medium (or another gel medium) for a second prescribed time.

FIGS. 1B and 1C illustrate magnified views showing how the gel medium 16 can etch a surface material. As shown in FIGS. 1A-1C, a gel medium 16 is loaded with a liquid etchant 18, which is appropriate for etching a material to be removed. The gel medium 16, loaded with the liquid etchant 18, is passed over the surface of the integrated circuit 1, for example, using a laminar flow. The process chamber is made of a material or coated with a material resistant to etching, such as for example polytetrafluoroethane. In one embodiment of the invention, the integrated circuit 1 includes vias 14 filled with metal and includes an overburden 12 on the surface of the via structures. The etchant contained in the gel medium 16 does not penetrate into the small vertical interconnect structures, i.e. does not penetrate the vias 14 where the metal resides due to the size and etchant trapping nature of the gel medium 16.

One suitable material for a gel medium 16 is a gel medium manufactured by Nisene Technology Group. As noted above, the gel medium 16 is loaded with an appropriate liquid etchant 18 for the material to be removed. In one embodiment, the gel medium 16 is suitably selected to have a gel particle size (e.g., ˜1 mm) which is larger than a feature of interest (e.g., via structure 14 or deep trenches) of the integrated circuit 1. The etchant is chemically attached to the selected gel. By selecting an appropriate gel particle size, a material (e.g., overburden 12) can be removed from the surface of the integrated circuit 1 without overetching the metal filed vias.

The process in one embodiment is considered to be self-limiting. As shown in FIG. 1C, after gel medium 16 flows across the surface of an integrated circuit 1, the overburden is removed, and only a topmost part of the metal filled via 14 is removed. The gel particle size of the loaded gel medium 16 is large enough such that overburden 12 is removed without substantial removal of the metal from within the metal via.

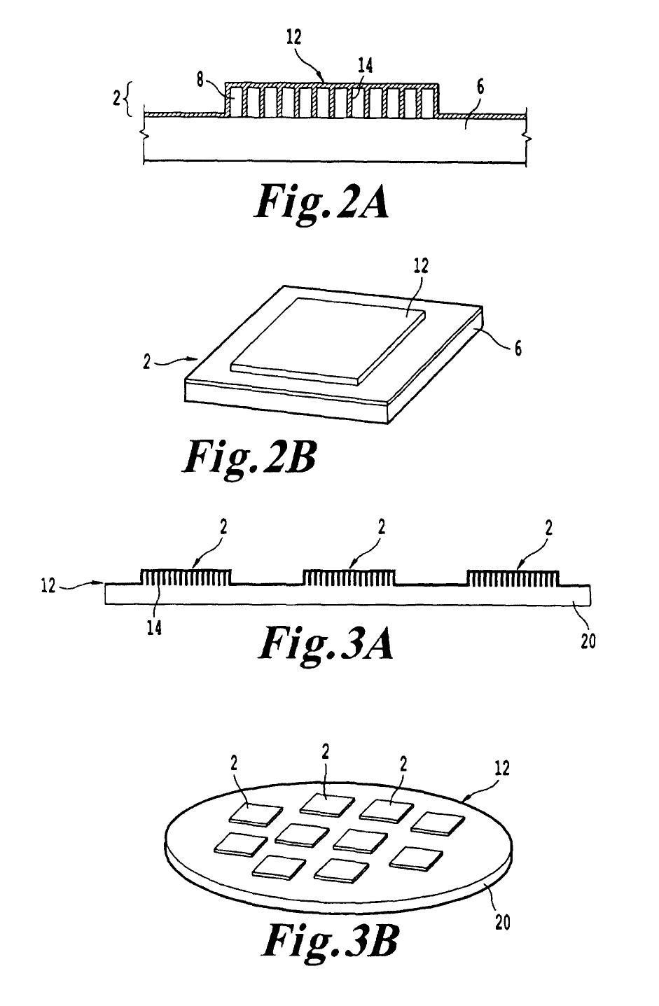

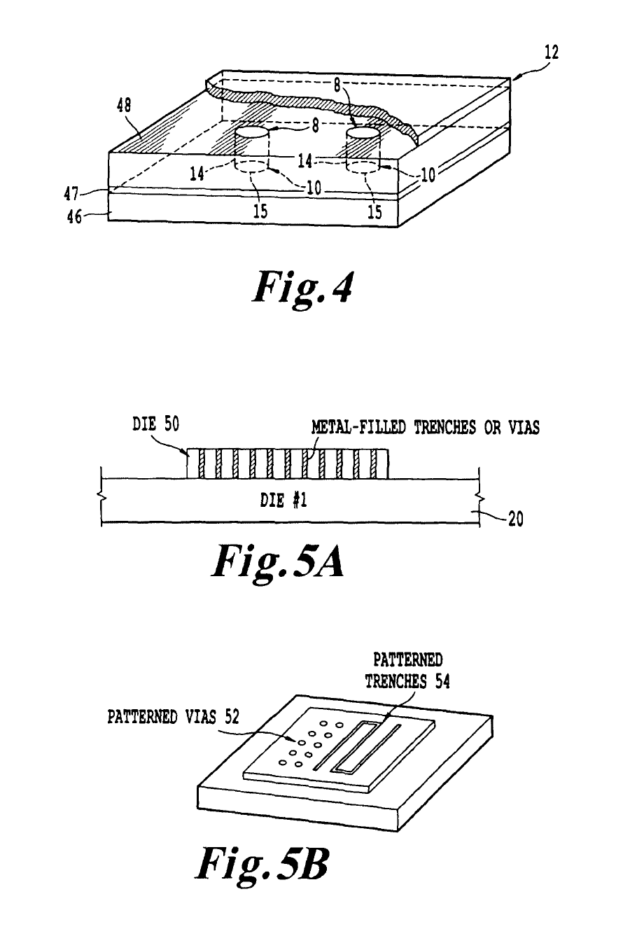

FIG. 2A illustrates a cross-section of an exemplary die-to-die configuration to which one embodiment of the invention is applied. A first die 2 including via wall structures 8 and via metal 14 is stacked and electrically integrated with a second die 6. The via structures 8 as shown in FIG. 2A are filled with a conductive material (e.g., copper). Other conducting materials can be used for the metal filled via 14 including aluminum and silicides. As a result of the filling of via wall structures 8, an overburden 12 is formed on the surface of the dies 2 and 6. FIG. 2B is a three-dimensional illustration of the integrated circuit of FIG. 2A in which the surface of the integrated circuit of FIG. 2A is entirely covered by the overburden 12. A more detailed view is shown in FIG. 4 (to be discussed below).

In one embodiment, the gel medium 16 carries a first etchant E₁ for a first prescribed amount of time before a gel medium with a second etchant E₂ is introduced for a second prescribed amount of time. In this embodiment, for example, the overburden 12 can first be removed during the first prescribed amount of time, and afterwards etchant E₂ for removal of part of a dielectric member wall around the via wall structures 8 can be used for the second prescribed amount of time. Alternatively, the second etchant could be used to remove a passivation layer over the surface of the dies 2.

FIG. 3A depicts a cross-section of an exemplary die-to-wafer configuration having multiple die 2 attached to a wafer or substrate 20. FIG. 3B illustrates a three-dimensional perspective schematic of the die-to-wafer configuration in FIG. 3A. Similar to the die-to-die configuration, the die-to-wafer configurations of FIGS. 3A and 3B include on die 2 a plurality of via wall structures including metal filled via 14. An overburden 12 exists on the surface of die 2 and wafer 20 in the die-to-wafer configuration after the filling of via structures 8 with via metal.

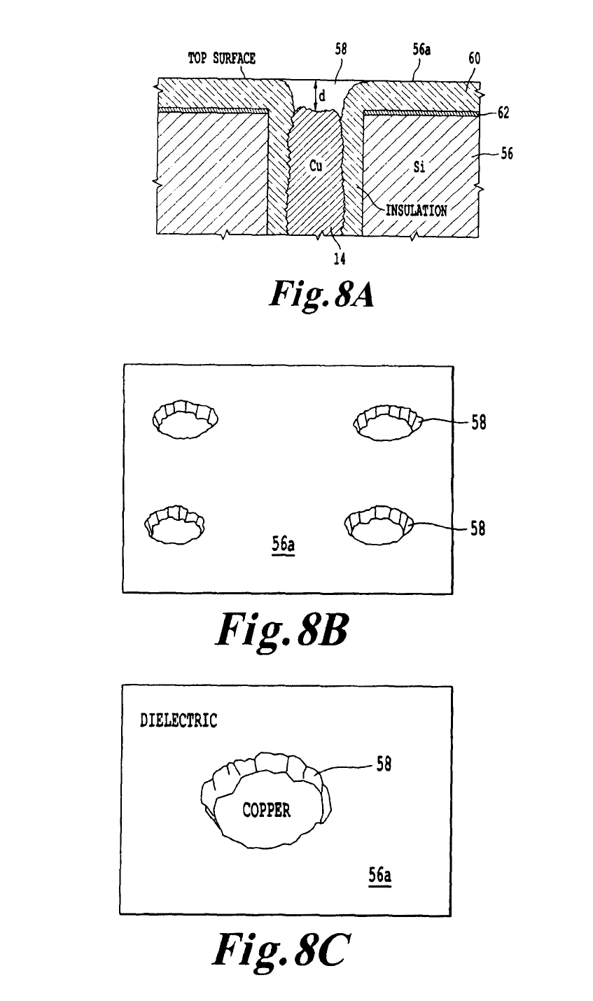

As shown in FIG. 4, in one embodiment, the integrated circuit includes a first device substrate 46 including at least one contact pad 10 formed on a top surface 15 of the first device substrate 46 and can include an optional overlying passivation layer 47. The first device substrate 46 is bonded to a second device substrate 48, after alignment of the device substrates 46 and 48. The second device substrate 48 includes at least one via wall structure 8 which for example can be bored through the second device substrate 48, and bored through the optional overlying passivation layer 47, to expose the contact pad 10. A via-fill metal is formed on the contact pad 10 and fills the via wall structure 8. Furthermore, in one embodiment of the invention, the sidewalls of the via 14 can be insulated with a dielectric (as shown in FIG. 8A to be discussed below).

The contact pad(s) 10, prior to formation of the via, may either be recessed, exposed, and/or passivated on the first device substrate 46. FIG. 4 shows a single upper substrate (i.e, second device substrate 48) bonded to a first device substrate 46. The upper substrate has multiple via fill metal 14 regions. In one embodiment, the multiple metal filled vias 14 in the upper substrate are included for connection to a plurality of device die.

FIGS. 5A and 5B are schematic illustrations of the appearance of stacked die 50 on wafer 20 after overburden removal using the loaded gel process of the invention. FIG. 5B shows patterned features including patterned vias 52 and patterned trench structures 54, exposed by the removal process discussed above with respect to FIGS. 1A-1C. In other words, by applying the surface material removal process of the invention, an overburden layer on a stacked die is removed to expose a patterned top of a via structure 52 or patterned trench structures 54.

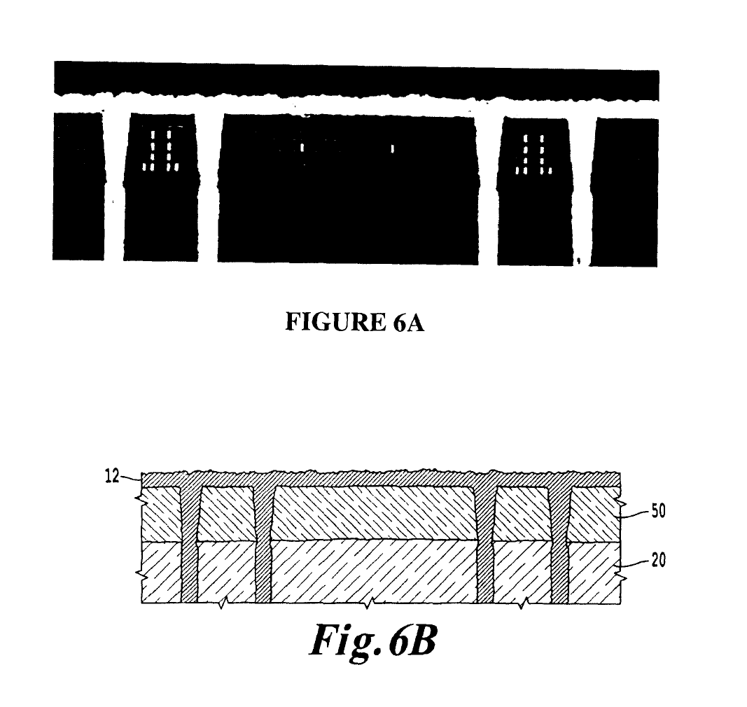

FIG. 6A shows an SEM micrograph of a cross section showing the copper overburden and filled copper vias in a die-to-wafer configuration. FIG. 6B is a schematic representation of the structure shown in FIG. 6A. As seen in FIG. 6A, the filled copper vias extend from the wafer 20 through to the top surface of die 50. The SEM reveals circuit structure in the die which for the sake of simplicity are not shown in FIG. 6B. FIGS. 6A and 6B illustrate the integration of metal lines through a substrate permitting three-dimensional integration of multiple die (including different types of die such as memory, logic, analog) onto a common wafer 20.

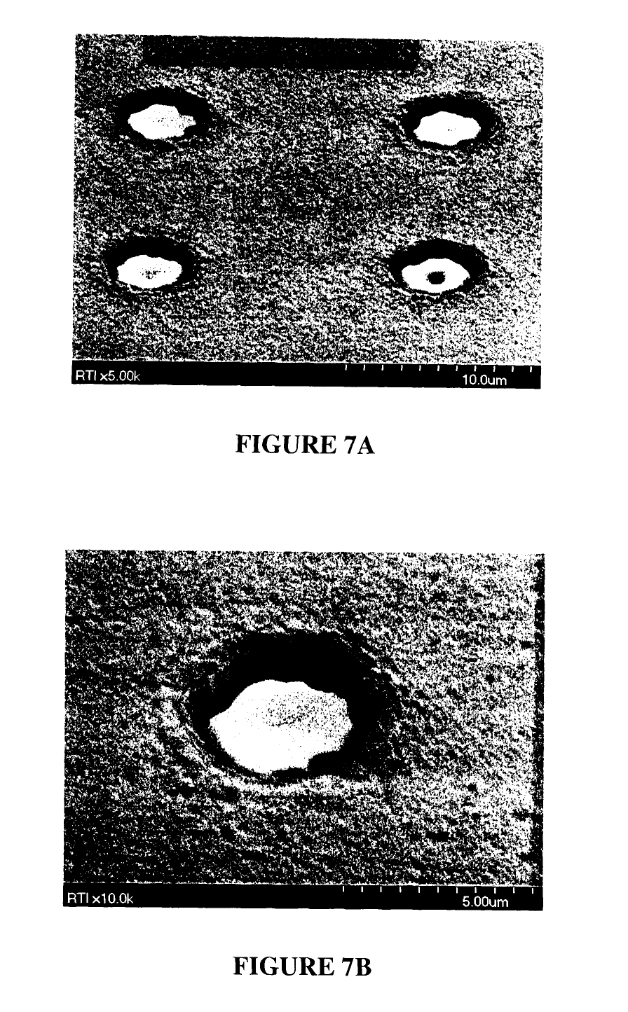

FIGS. 7A and 7B are SEM micrographs showing a topographical view of the surface of die 50 and the topmost part of the via metal after removal of the overburden layer 12. FIG. 8A is a schematic representation of a cross section SEM showing specifically copper overburden removal from the top of a die, leaving surface 56a (i.e., the surface of a passivation layer 60) bare of copper and depression 58 in the metal of filled via 14. As shown in FIG. 8A, the passivation layer 60 can be formed on the via walls to insulate the via metal from the die. Typical passivation layers include materials such as silicon oxide, silicon nitride, spin-on glass materials, and polymers such as for example parylene (a conformal polymer coating). As shown in FIG. 8A, the die 56 may have an insulating layer 62 on its top surface. After the overburden has been removed, as shown in FIG. 8A, typically a depression a depth d exists where the gel medium 16 etches below a surface of the passivation layer 60. The depth can range from 0.5 μm to 2 μm.

In one embodiment, the gel medium 16 can be used to etch away the top most passivation layer 60 to further planarize the local structure around the metal filled via 14. As a result, with the passivation layer 60 removed from the top, the resultant via structure would have the insulating layer 62, the remaining passivation layer 60 surrounding metal filled via 14, and the top surface of the metal filled via 14 nearly even with each other.

FIGS. 8B and 8C are schematic representations of the structure shown in FIGS. 7A and 7B. FIGS. 8B and 8C show the results in which the surface 56a of die 56 has no overburden and the via metal 14 has had the topmost part removed, leaving depressions 58 in the via wall structure 8.

Gel Medium

As discussed above, a gel medium containing an appropriate etchant is transposed across the surface of a stacked die (or multiple die on wafer). In one embodiment of the invention, the gel medium is a 36-6 Carrier Medium (“36-6”) available from Nisene Technology Group (Watsonville, Calif.). Properties of suitable carrier materials are listed below. A more detailed characterization of these commercially available carrier gels and the conventional use of these materials in delayering are found in the following Technical Bulletins from Nisene, whose contents are incorporated herein by reference.

#3000 mniEtch

3101 36-6 Carrier Medium

#3102 36-6 Carrier Medium: Physical Description

#3103 36-6 Carrier Medium: Chemical Description

#3204 Copper De-Layering

#3205 Aluminium De-Layering

#3206 Aluminium De-Layering SEM Results

#3301 Considerations of Chemical Backside Thinning of Die

36-6 is a hydrophilic polymer composed of complex polysaccharides. The physical properties of 36-6 are such that the polysaccharide complex can retain water through a combination of hydrogen bonding and/or the water can be held captive within the extensive network of inter and intra molecular voids found in the quaternary molecular structure. Chemical etch recipes typically contain water, or are water-soluble. The presence of water as a constituent of the etch recipe, or the miscibility of an etch recipe with nascent water bound in the molecule of 36-6 results in the etchant being absorbed onto the surface of the carrier medium particles. 36-6 is chemically inert and is fully compatible with a number of etch chemistries. 36-6 is suitable for a wide range of etch chemistries and conditions, and is successful from room temperature up to 45° C.

While the example of 36-6 is given above, in general, the gel medium 16 of the invention includes gels which are liquid-water-containing networks showing solid-like behavior with a characteristic strength that is dependent on their concentration, and a hardness and a brittleness that depends on the molecular structure of the hydrocolloid(s) composing the gels. Hydrocolloids can exhibit both elastic and viscous behavior. Elasticity occurs when the entangled polymers are unable to disentangle to allow flow. Often hydrocolloids exhibit a delicate balance between hydrophobicity and hydrophilicity. Negatively charged hydrocolloids can change their structural characteristics with counter-ion type and concentration (including pH and ionic strength effects); e.g. at high acidity the charges disappear and the molecules become less extended. Physical characteristics of hydrocolloids can be controlled by thermodynamics or kinetics dependent on concentration. Some hydrocolloids prefer low-density or higher density water while others exhibit compatibility with both. As more intra-molecular hydrogen bonds form, the hydrocolloids become more hydrophobic.

Examples of suitable classes of carrier gel mediums are provided below for the purpose of illustration and do not to necessarily limit the invention to any or all of these classes.

Polysaccharides

Polysaccharide (such as glycan) is suitable as a carrier gel medium for the invention and can include a configurational series of the monomer residues known by, D- or L-included as a prefix to the name:

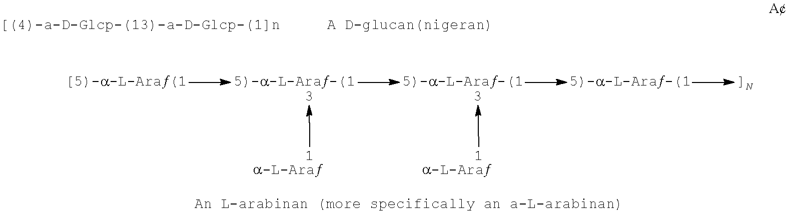

When specific sugars are designated, notation for glycosidic linkages precede the symbols designating the configuration of the sugar; thus, (14)-a-D-glucan.

Examples of these carrier gel mediums include:

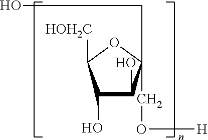

(21)-b-D-Fructofuranan (inulin has this structure, with a terminal a-D-glucopyranosyl group);

[4)-a-D-Glcp-(1] n; and

(14)-a-D-Glucopyranan (amylose)

Polysaccharides Composed of More than One Kind of Residue

Heteropolysaccharide (heteroglycan) is a polymer suitable as a carrier gel medium for the invention and containing two or more kinds of sugar (glycose) or modified sugar (e.g. aminodeoxyglycose or glycuronic acid) residue. When the polysaccharide has a principal chain (‘backbone’) composed of only one type of sugar residue, this residue is referred to by a ‘glycan’ term. Other types of residues known as ‘glyco-’ prefixes are also suitable as carrier gel mediums for the invention.

Glycoproteins, Glycopeptides and Peptidoglycans

Polymers containing covalently bound monosaccharide and amino-acid residues termed glycoproteins, glycopeptides or peptidoglycans are likewise suitable as carrier gel mediums in the invention. In general, glycoproteins are conjugated proteins containing either oligosaccharide groups or polysaccharide groups having a fairly low relative molecular mass. Proteoglycans are proteins linked to polysaccharides of high molecular mass. Peptidoglycans consist of polysaccharide chains covalently linked to peptide chains. Neoglycoproteins which are ynthetically produced or modified carbohydrate-protein conjugates are likewise suitable as carrier gel mediums in the invention.

Chemical Processing

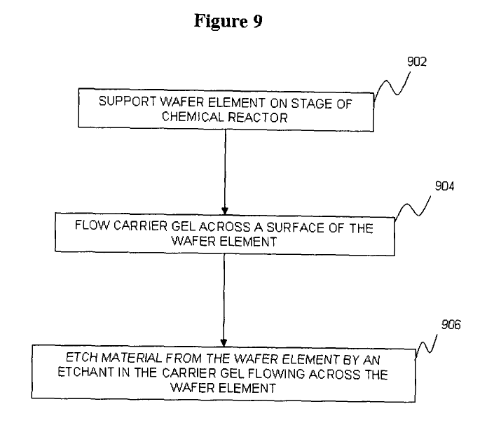

FIG. 9 is a flowchart illustrating a process of the invention for removing overburden and facilitating substrate stack integration. At 902, a wafer element is supported on a stage of a chemical reactor. At 904, a carrier-gel is flowed across the surface of the wafer element. The carrier gel includes an etchant for selectively etching a first material of a surface structure, and the carrier-gel has a gel particle size larger than the surface structure (e.g. larger than the via fill structure 14 shown in FIGS. 1A, 1B, and 1C. At 906, a material is etched from the wafer element by an etchant included in the carrier-gel flowing across the surface of the wafer element in order to remove a part of the first material from the surface structure for subsequent device fabrication.

At 904, the carrier-gel can flow over an irregular surface of the wafer element such as would be present when the wafer element is part of a stacked die on die or stacked die on wafer configuration as shown in FIGS. 2A and 3A, respectively. Further, the carrier-gel can flow over at least one metallized via structure such as shown for example in FIGS. 2A and 3A. At 904, the carrier-gel can be pumped into a chemical reactor to create a laminar flow of the carrier-gel across the surface of the wafer element, as shown in FIG. 1. The laminar flow brings fresh etchant to the overburden to remove the overburden material progressively with time.

At 904, the carrier-gel can include gel particles having sizes larger than a surface feature in which the material to be etched exists (e.g., larger than a via hole of the wafer element). Indeed, the carrier-gel in different embodiments has gel particles of a size at least two times larger than the surface structure to be etched, or at least five times larger than the surface structure to be etched, or at least ten times larger than the surface feature to be etched. The larger the gel particle size relative to the surface structure to be etched, the less likely the surface structure will be overetched. For example, carrier-gel can have gel particle sizes of approximately 100 μm, or 60 to 100 or larger than 3 μm. The carrier-gel can be a hydrophilic polymer including the etchant, or a polysaccharide including the etchant, or a hydrocolloid including the etchant. The carrier-gel can be at least one of glycoproteins, glycopeptides, or peptidoglycans, which would respectively include the etchant.

At 906, the overburden layer is removed which exists across at least one via structure of a wafer element. The overburden can exist on the surfaces of the stacked die and a base substrate holding the stacked die. The overburden removal removes a portion of the metal 14 in the topmost of the via holes as shown for example in FIG. 8. 13. The overburden can be removed from the via structure to a depth that is within the carrier gel particle size. The overburden layer can include layers of copper, aluminum, tungsten or silicide or a combination thereof.

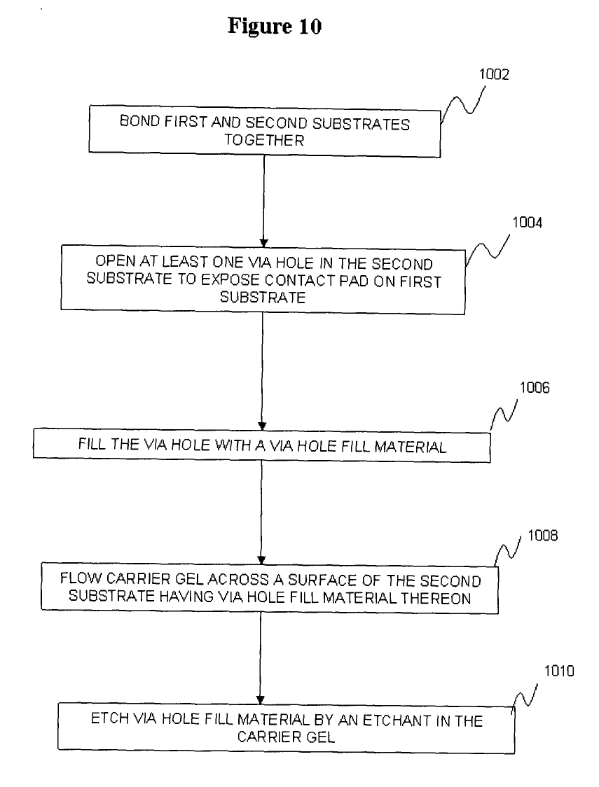

FIG. 10 is a flowchart illustrating another process of the invention for removing overburden and facilitating substrate stack integration. At 1002, a first substrate and a second substrate are bonded together. At 1004, at least one via hole is opened in the second substrate to expose at least one contact of the first substrate. At 1006, the at least one via hole is filled with a via-fill material. At 1008, a carrier-gel is flowed across a surface of the second substrate having the via-fill material thereon. At 1010, excess of the via-fill material is etched by an etchant included in the carrier-gel flowing across the surface of the first and second substrates.

Of the process depicted in FIG. 10, process elements 1008 and 1010 can include the process elements discussed above with regards to process elements 904 and 906 in FIG. 9.

Such process elements depicted in FIG. 10 can be accomplished in a system which includes 1) a bonder configured to bond the first and second substrates, 2) a via former configured to form at least one via hole in the second substrate to expose at least one contact of the first substrate, 3) a depositor configured to fill the at least one via hole with a via-fill material, and 4) a chemical reactor including a stage for support of a workpiece, such as for example the bonded first and second substrate pair, and configured to flow a carrier-gel across a surface of the second substrate having said via-fill material thereon to thereby remove excess of the via-fill material by an etchant in the carrier-gel.

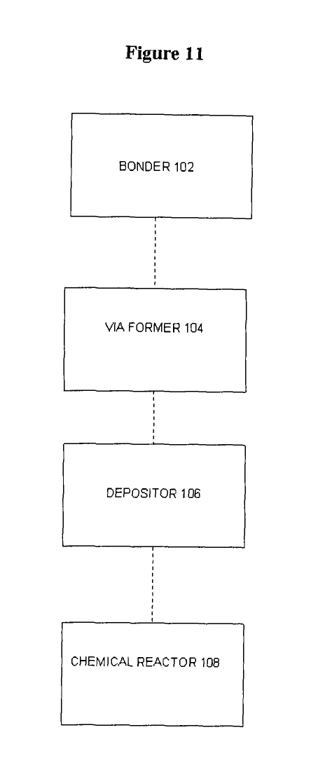

FIG. 11 is a schematic depicting the elements of such a system. The system 100 shown in FIG. 11 is for illustration purposes of various embodiments of the invention. The system in FIG. 11 can include for bonder 102 a pressure/temperature bonder, although other wafer and die bonding equipment can be used. Pressure/temperature bonders and techniques for wafer preparation and handling suitable for the invention are described in U.S. Pat. Appl. Publ. No. 2006/0292823, the entire contents of which are incorporated herein by reference. One suitable bonder is the Suss MicroTec FC-150 device bonder. The system in FIG. 11 can include for via former 104 a photographic mask layout and deep reactive ion etcher. The via former 104 can include for example a UV exposure and developer forming a patterned photoresist mask. One suitable exposure tool is the Suss MA-8 mask aligner. The via former 104 can include for example an inductively coupled plasma etcher. One suitable etcher is a Multiplex Advanced Silicon Etcher by Surface Technology Systems (STS) (Imperial Park, Newport, United Kingdom) with an inductively coupled plasma (ICP) source. This system has a 1 kW RF power source (13.56 MHz) for the coil and a 300 W RF power source (13.56 MHz) for the platen, which are controlled independently of each other.

The system in FIG. 11 can include for depositor 106 a Cu electroplating system such as described in U.S. Pat. No. 6,121,149, the entire contents of which are incorporated herein by reference. Examples of suitable electroplating tools are wafer plating cells manufactured by Technic, Inc. Besides electroplating, Cu or other via materials can be deposited in the invention using metal organic chemical vapor deposition (MOCVD) carriers such as for example using hexafluoroacetylacetonate copper vinyltrimethylsilane at a deposition temperature of 180° C. or higher. The system in FIG. 11 can include for the chemical reactor 108 the equipment described above with regard to FIG. 1A providing suitable etchants in the carrier gel medium 16 discussed above.

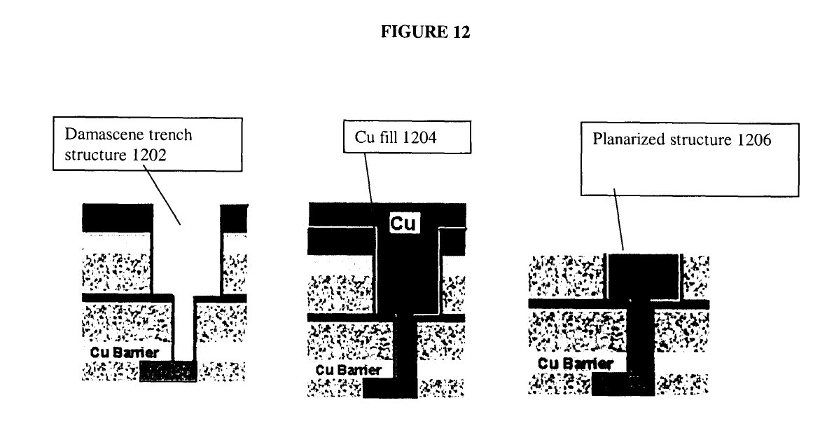

Beside applicability to the via trench overburden removal described above for the simple vertical trench structures shown in FIG. 8A, the overburden removal of the invention is likewise suited for the removal of excess via fill materials after deposition in more complex trench structures. One such example would the removal of Cu overburden following the deposition of Cu in dual damascene vias. FIG. 12 shows a dual damascene trench structure in which that formation process is modified in accordance with the invention. After formation of the trench structure 1202, a metal deposition 1204 fills the trench 1202 typically with Cu. The standard chemical mechanical polish (CMP) is replaced with a carrier gel etch for Cu removal. As above, the carrier gel etch would use a carrier gel medium whose gel particle size was larger than the top most trench opening in the trench structure 1202 and include an etchant such as those used in the CMP process to remove the Cu overfill. The Cu overfill can be removed to a depth that is within the gel particle size, producing the planarized structure 1206 on top of the dual damascene plug.

Indeed, one issue with the conventional CMP process is that this process applies mechanical stress to the surface of the trench structure. Due to the trench structure 1202 being formed typically in a low-k dielectric materials (such as for example porous oxides), the trench structure 1202 is not as robust as other semiconductor structures against CMP. Here, in one embodiment of the invention, the carrier gel provides a controllable mechanism for delivery of a Cu etchant to remove the overburden in a flow of the carrier gel medium across the Cu filled structure 1204, and removal of Cu beneath the upper surface of the trench structure 1202 is inhibited by the carrier gel having a particle size larger than a diameter of the opening at the top of the trench structure 1202.

Accordingly, the system 100 shown in FIG. 11 is a system for treating a surface structure of a workpiece that includes a chemical reactor configured to flow a carrier-gel to the surface structure of the workpiece, where the carrier gel includes an etchant for selectively etching a first material of the surface structure and the etchant has a gel particle size larger than the surface structure. The chemical reactor can flow the carrier-gel over an irregular surface of the workpiece, can flow the carrier-gel over at least one metallized via structure on the workpiece, and can flow the carrier-gel over at least one metallized damascene structure.

The chemical reactor can remove an overburden layer existing across at least one via structure of the workpiece and on a surface of the workpiece removed from the at least one via structure. The chemical reactor can remove for the overburden layer at least one of copper, aluminum, tungsten and silicide or a combination thereof, by the inclusion in the carrier gel of appropriate etchants known to respectively etch those materials. The chemical reactor can pump the carrier-gel across the workpiece to create a laminar flow of the carrier-gel across the surface of the workpiece.

The chemical reactor can provide for the carrier-gel having gel particles having a size at least two times larger than the surface structure to be etched, or at least five times larger than the surface feature to be etched, or at least ten times larger than the surface feature to be etched. The carrier-gel pumped can be a hydrophilic polymer, a polysaccharide, a hydrocolloid, and/or at least one of glycoproteins, glycopeptides, or peptidoglycans for the carrier gel.

The via former 104 of system 100 can form at least one via hole in the workpiece. The via former 104 can form for the at least one via hole a damascene structure. The depositor can fill the at least one via hole or the damascene structure with a via-fill material using for example the electroplating or the MOCVD techniques described above.

The processes described above can be applied to workpieces other than wafers used in semiconductor processing. The other types of workpieces include multilayer printed circuit boards (PCBs), display or solar cell panels, for example. Further, workpeices of the invention can include any other substrates on which multilayer metal routing lines are fabricated to create an electronic backplane. PCBs frequently incorporate vias between the PCB layers which are filled with conductive materials. The application of the gel-based planarization process of the invention can remove the material from the top surface of the layer (while leaving the material in the via) resulting in a surface on which the routing lines can be easily patterned. Display and solar cell panels are typically rectangular in shape and made of glass, polymer or metal. Multilayer metal structures are fabricated on the panels to provide signal routes from the electronic subsystem to light emitting or light harvesting device areas. Furthermore, the workpieces described above do not have to be planar. The gel-based planarization process applies to curved substrates, such as might be used for displays and solar cells, or to spherical substrates such as are considered for niche electronic applications.

Numerous modifications and variations of the invention are possible in light of the above teachings. It is therefore to be understood that within the scope of the appended claims, the invention may be practiced otherwise than as specifically described herein.

1. A method for treating a surface of a first workpiece having a through-hole structure extending to a second workpiece, comprising:
providing a carrier-gel to the surface of the first workpiece, said carrier-gel including an etchant for selectively etching a first material from the surface of the first workpiece and having a gel particle size larger than the through-hole structure; and
etching the first material from the surface of the first workpiece by a reaction of the etchant included in the carrier-gel with the first material of the surface of the first workpiece in order to remove a part of the first material from the surface and exposing the through-hole structure for subsequent device fabrication, without substantial removal of the first material from within the through-hole structure.

2. The method of claim 1, wherein providing a carrier-gel comprises:
flowing the carrier-gel over an irregular surface of the first workpiece.

3. The method of claim 1, wherein providing a carrier-gel comprises:
flowing the carrier-gel over at least one metallized via structure on the first workpiece.

4. The method of claim 3, wherein providing a carrier-gel comprises:
flowing the carrier-gel over at least one metallized damascene structure.

5. The method of claim 1, wherein removing a part of the first material comprises:
removing an overburden layer existing across through-hole structure of the first workpiece and on a surface of the first workpiece removed from the through-hole structure.

6. The method of claim 5, wherein etching the first material comprises:
removing for the overburden layer at least one of copper, aluminum, tungsten and silicide or a combination thereof.

7. The method of claim 1, wherein providing a carrier-gel comprises:
providing a laminar flow of the carrier-gel across the surface of the first workpiece.

8. The method of claim 1, wherein providing a carrier-gel comprises:
providing a carrier-gel including gel particles having a size at least two times larger than the through-hole structure to be etched.

9. The method of claim 1, wherein providing a carrier-gel comprises:
providing a carrier-gel including gel particles having a size at least five times larger than the through-hole structure to be etched.

10. The method of claim 1, wherein providing a carrier-gel comprises:
providing a carrier-gel including gel particles having a size at least ten times larger than the through-hole structure to be etched.

11. The method of claim 1, wherein providing a carrier-gel comprises:
flowing at least one of a hydrophilic polymer, a polysaccharide, and a hydrocolloid across the through-hole structure of the first workpiece.

12. The method of claim 1, wherein providing a carrier-gel comprises:
flowing at least one of glycoproteins, glycopeptides, or peptidoglycans across the through-hole structure of the first workpiece.

13. The method of claim 1, wherein removing a part of the first material comprises:
removing said first material in the through-hole structure to a depth that is within the gel particle size.

14. The method of claim 1, wherein removing a part of the first material comprises:
removing said first material from a filed via structure.

15. The method of claim 1, wherein removing a part of the first material comprises:
removing said first material from a dual damascene structure.

16. The method of claim 1, wherein removing a part of the first material comprises:
removing said first material from a printed circuit board structure.

17. The method of claim 1, wherein removing a part of the first material comprises:
removing said first material from a display panel structure.

18. The method of claim 1, wherein removing a part of the first material comprises:
removing said first material from a solar panel structure.

19. A method for substrate processing, comprising:
opening at least one via in a first workpiece;
filling the at least one via with a via-fill material;
attaching the first workpiece to a second workpiece to form a bonded pair;
flowing a carrier-gel across a surface of the first workpiece having said via-fill material thereon; and
etching an excess of the via-fill material by an etchant included in the carrier-gel flowing across the surface of the first workpiece, without substantial removal of the via-fill material from the at least one via.

20. The method of claim 19, wherein flowing a carrier-gel comprises:
flowing a carrier-gel having a gel particle size larger than the at least one via.

21. The method of claim 19, wherein etching the first material comprises:
removing an overburden layer existing across the at least one via and existing on the surface of the first workpiece.

22. The method of claim 21, wherein removing an overburden layer comprises:
removing for the overburden layer at least one of copper, aluminum, tungsten and silicide or a combination thereof.

23. The method of claim 19, wherein providing a carrier-gel comprises:
providing a laminar flow of the carrier-gel across the surface structure of the first workpiece.

24. The method of claim 19, wherein providing a carrier-gel comprises:
providing a carrier-gel including gel particles having a size at least two times larger than a surface structure of the at least one via to be etched.

25. The method of claim 19, wherein providing a carrier-gel comprises:
providing a carrier-gel including gel particles having a size at least five times larger than a surface feature of the at least one via to be etched.

26. The method of claim 19, wherein providing a carrier-gel comprises:
providing a carrier-gel including gel particles having a size at least ten times larger than a surface feature of the at least one via to be etched.

27. The method of claim 19, wherein providing a carrier-gel comprises:
flowing at least one of a hydrophilic polymer, a polysaccharide, and a hydrocolloid across the surface of the first substrate having said via-fill material thereon.

28. The method of claim 19, wherein providing a carrier-gel comprises:
flowing at least one of glycoproteins, glycopeptides, or peptidoglycans across the surface of the second substrate having said via-fill material thereon.

29. (canceled)

30. The method of claim 19, wherein etching excess of the via-fill material comprises:
etching the excess of the via-fill material from a damascene structure in the workpiece.

31. The method of claim 19, wherein etching excess of the via-fill material comprises:
removing said first material in the at least one via to a depth that is within the gel particle size.

32. The method of claim 19, wherein etching excess of the via-fill material comprises:
removing said first material from a filled via structure.

33. The method of claim 19, wherein etching excess of the via-fill material comprises:
removing said first material from a dual damascene structure.

34. The method of claim 19, wherein etching excess of the via-fill material comprises:
removing said first material from a printed circuit board structure.

35. The method of claim 19, wherein etching excess of the via-fill material comprises:
removing said first material from a display panel structure.

36. The method of claim 19, wherein etching excess of the via-fill material comprises:
removing said first material from a solar panel structure.

37. A system for treating a surface structure of a first workpiece and a second workpiece of a bonded pair, comprising:
a chemical reactor supporting the bonded pair, said chemical reactor configured to:
flow a carrier-gel across the bonded pair, said carrier-gel including an etchant for selectively etching a first material of the surface structure and having a gel particle size larger than the surface structure; and
etch the first material from the surface structure of the bonded pair by a reaction of the etchant included in the carrier-gel with the first material of the surface structure in order to remove a part of the first material from the surface structure of the bonded pair for subsequent device fabrication.

38. The system of claim 37, wherein the chemical reactor is configured to:
flow the carrier-gel over an irregular surface of the bonded pair.

39. The system of claim 38, wherein the chemical reactor is configured to:
flow the carrier-gel over at least one metallized via structure on the first workpiece.

40. The system of claim 39, wherein the chemical reactor is configured to:
flow the carrier-gel over at least one metallized damascene structure.

41. The system of claim 37, wherein the chemical reactor is configured to:
remove an overburden layer existing across at least one via structure of the first workpiece and on a surface of the first workpiece removed from the at least one via structure.

42. The system of claim 41, wherein the chemical reactor is configured to:
remove for the overburden layer at least one of copper, aluminum, and silicide or a combination thereof.

43. The system of claim 37, wherein the chemical reactor is configured to:
provide a laminar flow of the carrier-gel across the bonded pair.

44. The system of claim 37, wherein the chemical reactor is configured to:
provide a carrier-gel including gel particles having a size at least two times larger than the surface structure to be etched.

45. The system of claim 37, wherein the chemical reactor is configured to:
provide a carrier-gel including gel particles having a size at least five times larger than the surface structure to be etched.

46. The system of claim 37, wherein the chemical reactor is configured to:
provide a carrier-gel including gel particles having a size at least ten times larger than the surface structure to be etched.

47. The system of claim 37, wherein the chemical reactor is configured to:
flow at least one of a hydrophilic polymer, a polysaccharide, and a hydrocolloid across the surface structure of the first workpiece.

48. The system of claim 37, wherein the chemical reactor is configured to:
flow at least one of glycoproteins, glycopeptides, or peptidoglycans across the surface structure of the first workpiece.

49. The system of claim 37, wherein the chemical reactor is configured to remove said first material in the surface structure to a depth that is within the gel particle size

50. The system of claim 37 wherein the chemical reactor is configured to remove said first material in a filled via structure.

51. The system of claim 37 wherein the chemical reactor is configured to remove said first material in a dual damascene structure.

52. The system of claim 37 wherein the chemical reactor is configured to remove said first material in a printed circuit board structure.

53. The system of claim 37 wherein the chemical reactor is configured to remove said first material in a display panel structure.

54. The system of claim 37 wherein the chemical reactor is configured to remove said first material in a solar panel structure.

55. The system of claim 37, further comprising:
a via former configured to form at least one via hole in the first workpiece; and
a depositor configured to fill the at least one via hole with a via-fill material.

56. The system of claim 37, further comprising:
a bonder configured to bond a first substrate to a second substrate to form the bonded pair;
a via former configured to form at least one via hole in the second substrate to expose at least one contact of the first substrate; and
a depositor configured to fill the at least one via hole with a via-fill material.

57. A system for substrate structure processing, comprising:
a via former configured to form at least one via hole in a first workpiece;
a depositor configured to fill the at least one via hole with a via-fill material;
a bonder configured to bond a second workpiece to the first workpiece to form a bonded pair; and
a chemical reactor supporting the bonded pair and configured to:
flow a carrier-gel across a surface of the first workpiece having said via-fill material thereon; and
etch excess of the via-fill material by an etchant included in the carrier-gel in order to remove a part of the first material from the surface structure for subsequent device fabrication.
